(19) United States
(12) Patent Application Publication
(10) Pub. No.: US 2007/0246514 A1
(43) Pub. Date: Oct. 25, 2007

(54) Method for Reflow Soldering

(76) Inventors: Horst Lettner, Aschaffenburg (DE); Rolf Diehm, Wertheim (DE)

Correspondence Address: BIRCH STEWART KOLASCH & BIRCH, PO BOX 747, FALLS CHURCH, VA, 22040-0747, US

(21) Appl. No.: 11/578,263

(22) PCT Filed: Apr. 6, 2005
(86) PCT No.: PCT/EP05/03611

§ 371 Date: May 19, 2007

(30) Foreign Application Priority Data
Apr. 13, 2004 (DE) 10 2004 017 772.4

(51) Int. Cl. B23K 1/002; H05K 3/00

(52) U.S. Cl. 228/177; 228/46

(57) ABSTRACT

The invention relates to a method and a device for the reflow soldering of circuit-board conductors with components and modules applied to a printed-circuit board by means of a solder paste, wherein, through radiation of an electromagnetic wave, an absorption material absorbing the radiation is heated and said heating is transferred to the solder paste for melting a solder contained in the solder paste. The solder paste is mixed with the absorption material to form a mixed material and the mixed material is applied to the soldering joints of the circuit-board conductors.

The invention relates to a method for the reflow soldering, using a solder paste, of circuit-board conductors with components and modules applied to a printed-circuit board by means of a solder paste, wherein, through radiation of an electromagnetic wave, an absorption material absorbing the radiation is heated and said heating is transferred to the solder paste for melting a solder contained in the solder paste.

Such a method is described in UK patent application GB 2 376 201 A. This method is used to join two components together by soldering, for which purpose a layer of solder is placed between the soldering joints of the components and, in the case of at least one component, a layer of an absorption material reacting to electromagnetic radiation is brought into contact with the solder layer. The absorption material is then exposed to the electromagnetic radiation, which generates a heat in the absorption material, said heat causing the solder layer to melt and thus the two components to be soldered together.

With this method, there is the effect that, during the entire time of the heating of the absorption material, said absorption material supplies heat to the soldering joints to be soldered and therefore also to the components, because it must be ensured that not only the solder, but also the soldering joints of the components are brought to the high temperature required for soldering. Consequently, the heat required for this method is considerable, which means that the components also undergo an especially high degree of heating, which is frequently detrimental to said components.

The object of the invention is to minimize the amount of heat produced and to be supplied through the absorption material. The object of the invention is achieved in that the solder paste is mixed with the absorption material to form a mixed material and the mixed material is applied to the soldering joints of the circuit-board conductors.

With this method, the heat required for melting the solder is supplied briefly, in particular: abruptly, to the solder and the soldering joints by means of the heating concentrated on the absorption material by the electromagnetic wave, because the absorption material is mixed with the solder paste, with the consequence that the resulting mixed material, which also contains the solder, is able to transfer its heat, produced by absorption, directly and by the shortest distance to the solder, which therefore undergoes a particularly intensive direct heating, this resulting in fast soldering at soldering joints. There is only a negligible further raising of the temperature of the components and modules, with the result, therefore, that the latter cannot be damaged.

It is normally sufficient if the mixed material is applied to the solder joint at the respective point of the circuit-board conductor. It is, however, also possible to apply the mixed material both to the respective circuit-board conductor and also to the contact points of the component or module.

In order to keep the heating of the soldering joints through the radiation of the electromagnetic wave as short as possible, it is advantageous, by means of heating acting from outside on the soldering joints, for the soldering joints to be preheated to a temperature of the solder below the melting temperature and then for the soldering joints to be brought abruptly to the melting temperature of the solder by means of the electromagnetic wave. The first-mentioned heating may be, for example, an infrared radiation or convection heating.

An additional heating of the soldering joints for the purpose of reducing the required energy at the soldering joints can be advantageously accomplished in that a lacquer layer is applied to the respective part of the soldering joint, the absorption material having been admixed to said lacquer layer. In this case, the respective part is selectively heated, said heating being additionally transferred to the soldering joints via the circuit-board conductors.

The solder paste used in the method according to the invention is a commercially available material of the kind available for reflow soldering. Admixed to this solder paste is the absorption material, which consists, for example, of a metal powder with a binding agent. However, the powder may also be composed of metal oxides of the kind known with regard to their property of absorbing electromagnetic waves.

Illustrative embodiments of the invention are presented in the drawings, in which:

FIG. 1 shows the soldering joint of a circuit-board conductor with a module, said soldering joint having been prepared for soldering;

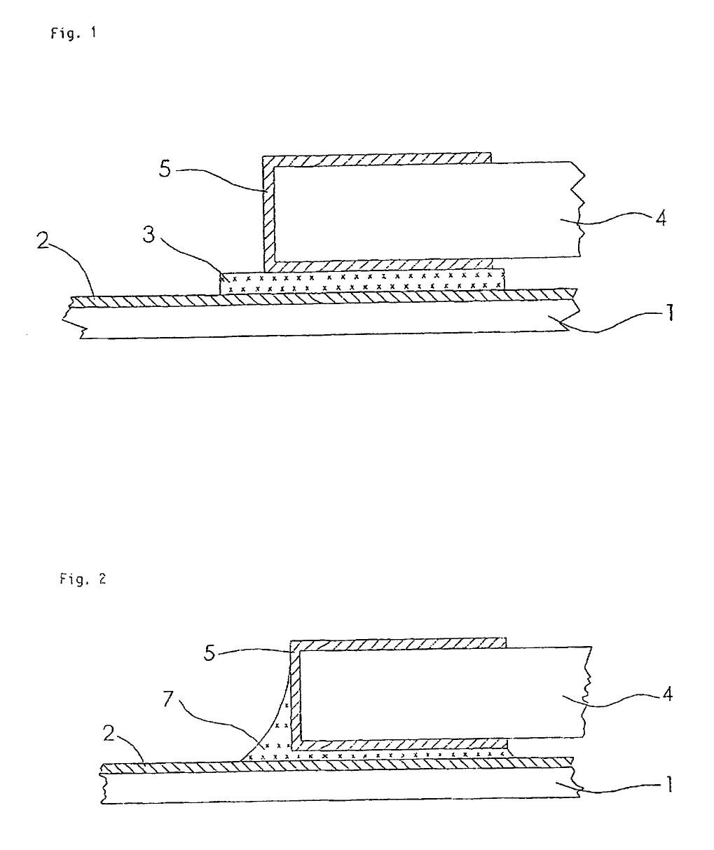

FIG. 2 shows a finish-soldered soldering joint;

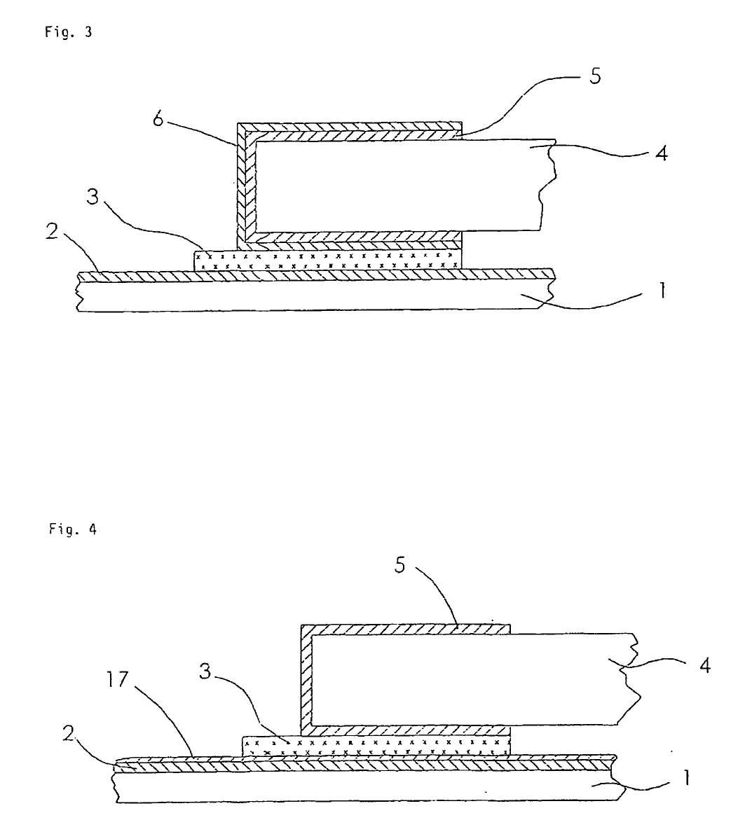

FIG. 3 shows a similar soldering joint in which the module is additionally provided in the region of its soldering joint with a lacquer layer to which the absorption material has been admixed;

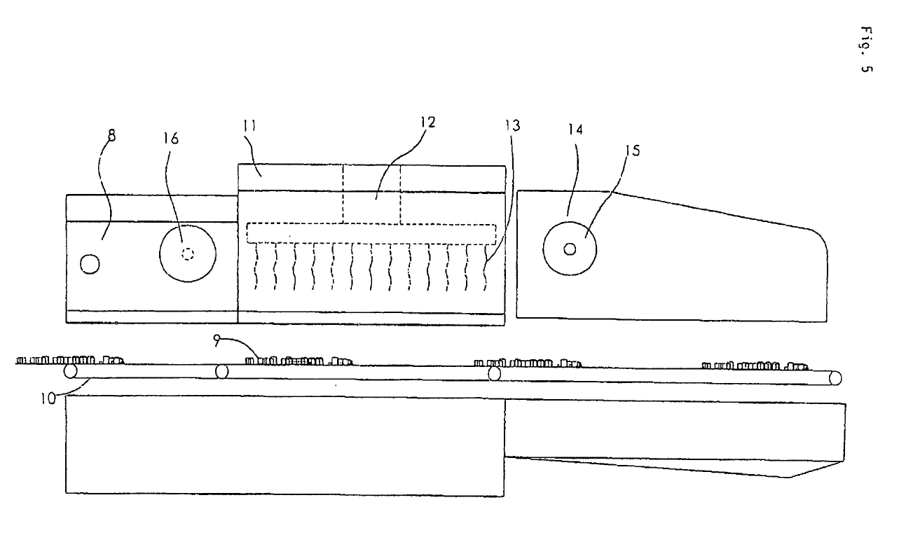

FIG. 4 shows a similar soldering joint in which the circuit-board conductor is additionally provided in the region of its soldering joint with a lacquer layer to which the absorption material has been admixed;

FIG. 5 shows a device for implementing the method according to the invention.

FIG. 1 shows a portion of a printed-circuit board 1 to which has been applied the circuit-board conductor 2, which is, for example, a copper layer. In the region of the later soldering joint, the circuit-board conductor 2 is provided with a pad 3 of the mixed material, said mixed material consisting of a solder paste and an admixed absorption material. Positioned on the pad 3 is the module 4, which is provided with the contact point 5, which, via the pad 3, is held in tight connection with the circuit-board conductor 2. Such a connection for later reflow soldering is known.

FIG. 2 shows the printed-circuit board 1 with the module 4 from FIG. 1 in the soldered state. As can be seen, the pad 3 from FIG. 1 has become the soldering joint 7, which joins the contact point 5 of the module 4 to the circuit-board conductor 2 by means of a continuous soldered connection.

FIG. 3 shows a variation of the arrangement according to FIG. 1 in which there is an additional lacquer layer 6 with which the contact point 5 is coated. Admixed to the lacquer layer 6 is the absorption material, which, when exposed to radiation from an electromagnetic wave, is heated and transfers its heat additionally to the pad 3, as a result of which the heat required by the pad 3 is correspondingly reduced.

FIG. 4 shows an arrangement similar to the arrangement in FIG. 3. In the arrangement in FIG. 4, the additional lacquer layer 17 has been applied to the circuit-board conductor 2 in the region where the pad 3 is situated. As in the arrangement shown in FIG. 3, in the arrangement in FIG. 4 the lacquer layer 17 is provided with the absorption material, with the result that, when exposed to radiation from the electromagnetic wave, the lacquer layer and therefore the circuit-board conductor 2 are heated and this heat is additionally transferred to the pad 3.

It should additionally be pointed out that, of course, the lacquer layers 6 and 17 shown in FIGS. 3 and 4 can also be applied together to the circuit-board conductor 2 and the contact point 5, this resulting in an especially intensive additional heating.

FIG. 5 shows a device for implementing the above-described method. The device contains three stages: the initial stage 8 for preheating the printed-circuit boards 9 by means of the fan heater 16, said printed-circuit boards 9 being transported through the device by a conveyor 10. The conveyor 10 is a customary known assembly of the kind used in soldering systems. The initial stage 8 is followed by the middle stage 11, which is provided with the radiator 12, the radiation from which is indicated by the wavy lines 13 issuing therefrom. This radiation consists of electromagnetic waves, more particularly microwaves which are, for example, in a frequency range from 300 MHz to 100 GHz. The radiation is then absorbed by the pads of mixed material applied to the soldering joints of the printed-circuit boards 9, it being the case that, owing to the preheating applied by the initial stage 8, the middle stage 11 only needs to provide a short burst of radiation in order to cause the solder contained in the mixed material to melt and thus to solder together the respective contact points. The middle stage 12 is then followed by the final stage 14, which serves to cool the soldered printed-circuit boards as they pass through the final stage 14. For this purpose, the final stage 14 is provided with an outlet 15 from which issues a cooled gas, more especially nitrogen,. However, the gas may also be cooled air. Thereafter, the printed-circuit boards 9 leave the final stage 14 in the form of finish-soldered printed-circuit boards.

1. Method for the reflow soldering of circuit-board conductors (2) with components and modules (4) applied to a printed-circuit board (1) by means of an individually the components respectively groups of components (4) related solder paste, wherein, through radiation of an electromagnetic wave, an absorption material absorbing the radiation is heated and said heating is transferred to the solder paste for melting a solder contained in the solder paste, characterized in that the solder paste is mixed with the absorption material to form a mixed material (3) and the mixed material (3) is applied to the soldering joints of the circuit-board conductors (2).

2. Method according to claim 1, characterized in that the mixed material (3) is applied to the circuit-board conductor (2) and the contact point (5) of the component and the module (4).

3. Method according to claim, characterized in that, by means of heating acting from outside on the soldering joints, the soldering joints are preheated to a temperature of the solder below the melting temperature and then the soldering joints are brought abruptly to the melting temperature of the solder by means of the electromagnetic wave.

4. Method according to claim 1, characterized in that, for additional heating of the soldering joints, a lacquer layer (6, 17) is applied to the respective part (2, 5) thereof, the absorption material having been admixed to said lacquer layer (6, 17).

5. Device for implementing the method according to claim 1, characterized in that said device contains at least three stages (8, 11, 14) traversed by a conveyor (10) transporting the printed-circuit boards (9), said three stages (8, 11, 14) being formed by an initial stage (8) for preheating the printed-circuit boards (9), a middle stage (11) for melting the solder and a final stage (14) for cooling the printed-circuit boards (9).

6. Soldering joint (7), produced by a method according to claim 1, characterized in that said soldering joint contains the solder from a mixed material melted by an electromagnetic wave.

7. Method according to claim 2, characterized in that, by means of heating acting from outside on the soldering joints, the soldering joints are preheated to a temperature of the solder below the melting temperature and then the soldering joints are brought abruptly to the melting temperature of the solder by means of the electromagnetic wave.

8. Method according to claim 2, characterized in that, for additional heating of the soldering joints, a lacquer layer (6, 17) is applied to the respective part (2, 5) thereof, the absorption material having been admixed to said lacquer layer (6, 17).

9. Method according to claim 3, characterized in that, for additional heating of the soldering joints, a lacquer layer (6, 17) is applied to the respective part (2, 5) thereof, the absorption material having been admixed to said lacquer layer (6, 17).

10. Device for implementing the method according to claim 2, characterized in that said device contains at least three stages (8, 11, 14) traversed by a conveyor (10) transporting the printed-circuit boards (9), said three stages (8, 11, 14) being formed by an initial stage (8) for preheating the printed-circuit boards (9), a middle stage (11) for melting the solder and a final stage (14) for cooling the printed-circuit boards (9).

11. Device for implementing the method according to claim 3, characterized in that said device contains at least three stages (8, 11, 14) traversed by a conveyor (10) transporting the printed-circuit boards (9), said three stages (8, 11, 14) being formed by an initial stage (8) for preheating the printed-circuit boards (9), a middle stage (11) for melting the solder and a final stage (14) for cooling the printed-circuit boards (9).

12. Device for implementing the method according to claim 4, characterized in that said device contains at least three stages (8, 11, 14) traversed by a conveyor (10) transporting the printed-circuit boards (9), said three stages (8, 11, 14) being formed by an initial stage (8) for preheating the printed-circuit boards (9), a middle stage (11) for melting the solder and a final stage (14) for cooling the printed-circuit boards (9).

13. Soldering joint (7), produced by a method according to claim 2, characterized in that said soldering joint contains the solder from a mixed material melted by an electromagnetic wave.

14. Soldering joint (7), produced by a method according to claim 3, characterized in that said soldering joint contains the solder from a mixed material melted by an electromagnetic wave.

15. Soldering joint (7), produced by a method according to claim 4, characterized in that said soldering joint contains the solder from a mixed material melted by an electromagnetic wave.
